(19) United States
(12) Patent Application Publication
(10) Pub. No.: US 2024/0421275 A1
(43) Pub. Date: Dec. 19, 2024

(54) DISPLAY SUBSTRATE, ENCAPSULATION SUBSTRATE, AND DISPLAY APPARATUS

(71) Applicant: BOE TECHNOLOGY GROUP CO., LTD., Beijing (CN)

(72) Inventors: Can WANG, Beijing (CN); Yan QU, Beijing (CN); Minghua XUAN, Beijing (CN); Mingxing WANG, Beijing (CN); Xuan LIANG, Beijing (CN); Fei WANG, Beijing (CN); Xue DONG, Beijing (CN); Qi QI, Beijing (CN); Mingkun YANG, Beijing (CN)

(73) Assignee: BOE TECHNOLOGY GROUP CO., LTD., Beijing (CN)

(21) Appl. No.: 18/701,618

(22) PCT Filed: Apr. 19, 2023
(86) PCT No.: PCT/CN2023/089107

§ 371 Date: Apr. 16, 2024

(30) Foreign Application Priority Data
Apr. 28, 2022 (CN) 202210461810.1

(51) Int. Cl. H01L 33/62; H01L 25/16; H01L 33/00; H01L 33/32

(52) U.S. Cl. CPC H01L 33/62; H01L 25/167; H01L 33/007; H01L 33/0093; H01L 33/32; H01L 2933/0066

(57) ABSTRACT

A display substrate includes a driving backplane, and a light-emitting device layer located on a side of the driving backplane. The light-emitting device layer includes a plurality of light-emitting units; a plurality of transparent electrodes which are located on surfaces of the plurality of light-emitting units away from the driving backplane and electrically connected to the light-emitting units; and a first bonding pattern which is at least located between the plurality of transparent electrodes. The first bonding pattern is electrically connected to at least one transparent electrode.

### CROSS-REFERENCE TO RELATED APPLICATIONS

This application is a national phase entry under 35 USC 371 of International Patent Application No. PCT/CN2023/089107, filed on Apr. 19, 2023, which claims priority to Chinese Patent Application No. 202210461810.1, filed on Apr. 28, 2022, which are incorporated herein by reference in their entirety.

### TECHNICAL FIELD

The present disclosure relates to the field of display technologies, and in particular, to a display substrate, an encapsulation substrate and a display apparatus.

### BACKGROUND

Light-emitting diodes (LEDs) are semiconductor components that can convert electrical energy into light within a specific wavelength range. The luminous principle of the light-emitting diode is recombination of electrons and holes to emit light.

Light-emitting diodes have low power consumption, small size, high brightness, easy to match with an integrated circuit, high reliability and other advantages, and are widely used as light sources currently. With the maturity of LED technology, LED display apparatuses or micro-LED display apparatuses that directly use LEDs as sub-pixels are gradually developing.

However, existing LED display apparatuses have high power consumption.

### SUMMARY

In an aspect, a display substrate is provided. The display substrate includes a driving backplane and a light-emitting device layer located on a side of the driving backplane. The light-emitting device layer includes a plurality of light-emitting units; a plurality of transparent electrodes located on surfaces of the plurality of light-emitting units away from the driving backplane and electrically connected to the light-emitting units; and a first bonding pattern at least located between the plurality of transparent electrodes. The first bonding pattern is electrically connected to at least one transparent electrode.

In some embodiments, the first bonding pattern is further located around the plurality of transparent electrodes.

In some embodiments, the first bonding pattern has a plurality of openings, an opening is provided with at least one transparent electrode therein, and the at least one transparent electrode located in the opening is electrically connected to a wall of the opening.

In some embodiments, the first bonding pattern includes a first pattern layer and a second pattern layer that are stacked, and the second pattern layer is located on a side of the first pattern layer away from the driving backplane.

In some embodiments, a material of the first pattern layer includes a first metal material, and a material of the second pattern layer includes a second metal material. A melting point of the first metal material is higher than a melting point of the second metal material.

In some embodiments, a size of the second pattern layer is larger than a size of the first pattern layer.

In some embodiments, a light-emitting unit includes at least two stacked vertical light-emitting diodes and a connection layer located between two adjacent vertical light-emitting diodes in the at least two stacked vertical light-emitting diodes. The vertical light-emitting diodes each include an N-type semiconductor layer, a quantum well layer and a P-type semiconductor layer. In the two adjacent stacked vertical light-emitting diodes, an N-type semiconductor layer of a vertical light-emitting diode and a P-type semiconductor layer of another vertical light-emitting diode are electrically connected by the connection layer.

In some embodiments, the display substrate further includes a reflective electrode layer located between the at least two stacked vertical light-emitting diodes and the driving backplane.

In some embodiments, the display substrate further includes an insulation structure located between the plurality of light-emitting units and between the first bonding pattern and the driving backplane.

In another aspect, an encapsulation substrate is provided. The encapsulation substrate includes a substrate, an electrode connection layer located on a side of the substrate, and a second bonding pattern located on a side of the electrode connection layer away from the substrate and exposing at least part of the electrode connection layer.

In some embodiments, the second bonding pattern includes a third pattern layer and a fourth pattern layer, and the third pattern layer is located on a side of the fourth pattern layer away from the substrate.

In some embodiments, a material of the third pattern layer includes a third metal material, and a material of the fourth pattern layer includes a fourth metal material. A melting point of the fourth metal material is higher than a melting point of the third metal material.

In some embodiments, a size of the third pattern layer is larger than a size of the fourth pattern layer.

In some embodiments, the encapsulation substrate further includes a plurality of lenses located between the substrate and the electrode connection layer. The second bonding pattern is at least located between the plurality of lenses.

In some embodiments, the substrate includes a base, a color filter layer located on a side of the base, and an encapsulation layer located on a side of the color filter layer away from the base. The encapsulation layer is disposed closer to the electrode connection layer than the color filter layer.

In some embodiments, the color filter layer includes a plurality of color filter portions and a light-shielding pattern located between adjacent color filter portions. An orthographic projection of the second bonding pattern on the base at least partially overlaps with an orthographic projection of the light-shielding pattern on the base.

In some embodiments, a color filter portion includes a color film layer and a quantum dot layer that are stacked. The color film layer is disposed closer to the base than the quantum well layer.

In yet another aspect, a display apparatus is provided. The display apparatus includes a display substrate as described in any of above embodiments and an encapsulation substrate as described in any of above embodiments. The first bonding pattern in the display substrate is bonded to the second bonding pattern in the encapsulation substrate, so that the plurality of transparent electrodes in the display substrate are in contact with the electrode connection layer in the encapsulation substrate.

In some embodiments, the second bonding pattern includes a third pattern layer and a fourth pattern layer, and the third pattern layer is located on a side of the fourth pattern layer away from the substrate.

In some embodiments, a material of the third pattern layer includes a third metal material, a material of the fourth pattern layer includes a fourth metal material, and a melting point of the fourth metal material is higher than a melting point of the third metal material. And/or, a size of the third pattern layer is larger than a size of the fourth pattern layer.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display substrate, in accordance with some embodiments of the present disclosure;

FIG. 2 is an equivalent circuit diagram of a driving circuit, in accordance with some embodiments of the present disclosure;

FIG. 3 is a top view of a display substrate, in accordance with some embodiments of the present disclosure;

FIGS. 4A to 4E are structural diagrams corresponding to all steps in a method for manufacturing stacked vertical light-emitting diodes, in accordance with some embodiments of the present disclosure;

FIG. 5A is a structural diagram of an encapsulation substrate, in accordance with some embodiments of the present disclosure;

FIG. 5B is a structural diagram of another encapsulation substrate, in accordance with some embodiments of the present disclosure; and

FIG. 6 is a structural diagram of a display apparatus, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The phrase “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

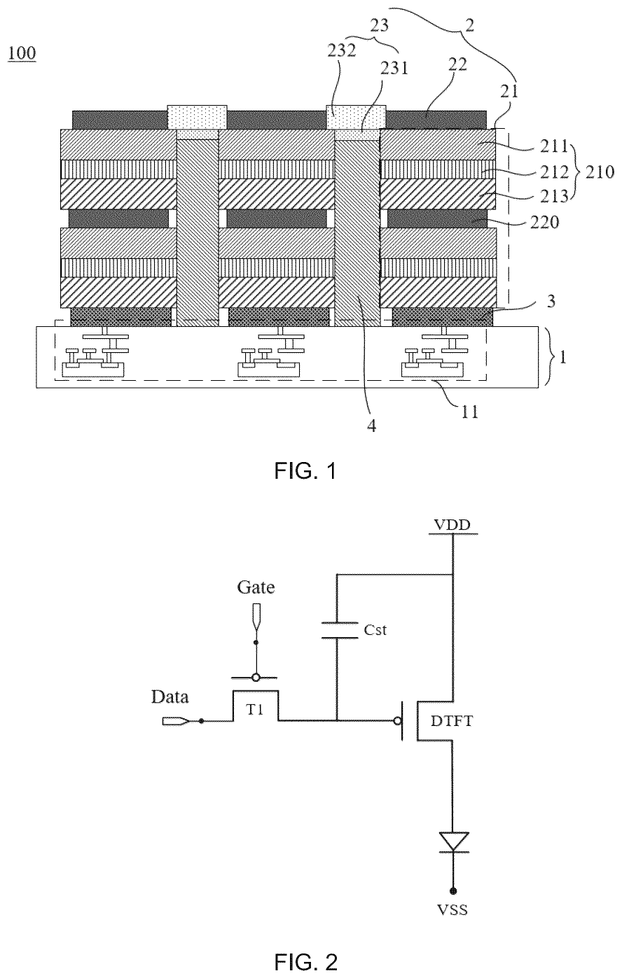

As shown in FIG. 1, some embodiments of the present disclosure provide a display substrate 100. The display substrate 100 includes a driving backplane 1 and a light-emitting device layer 2.

In some examples, the driving backplane 1 includes driving circuits 11, and a driving circuit 11 at least includes a switching transistor, a storage capacitor and a driving transistor. The driving circuit 11 may generate a driving signal. A light-emitting unit in the light-emitting device layer 2 emits light due to driving action of the driving signal generated by the driving circuit 11. Lights emitted by a plurality of light-emitting units cooperate with each other, so that the display substrate 100 realizes the display function.

The structure of the driving circuit 11 may vary, and may be set according to actual needs. For example, the structure of the driving circuit 11 may include a “2T1C” structure or an “8T1C” structure. Here, “T” represents a transistor, the number in front of “T” represents the number of the transistors, “C” represents a capacitor, and the number in front of “C” represents the number of the capacitor(s).

For example, as shown in FIG. 2, FIG. 2 is an equivalent circuit diagram of the driving circuit 11.

For example, the driving circuit 11 includes a driving transistor DTFT, a switching transistor T1 and a storage capacitor Cst.

A control electrode of the driving transistor DTFT is coupled to the switching transistor T1, a first electrode of the driving transistor DTFT is coupled to a first electrode of a light-emitting unit, and a second electrode of the driving transistor DTFT is coupled to a power signal terminal VDD. The specific type of the light-emitting unit may vary. For example, the light-emitting unit includes a blue-green light-emitting unit or a red-yellow light-emitting unit.

A first terminal of the storage capacitor Cst is coupled to the control electrode of the driving transistor DTFT, and a second terminal of the storage capacitor Cst is coupled to the power signal terminal VDD.

A control electrode of the switching transistor T1 is coupled to a scan signal terminal Gate, a first electrode of the switching transistor T1 is coupled to the control electrode of the driving transistor DTFT, and a second electrode of the switching transistor T1 is coupled to a data signal terminal Data.

For example, in a case where a level of a scan signal transmitted by the scan signal terminal Gate is an effective level, the switching transistor T1 is turned on under control of the scan signal to transmit a data signal transmitted by the data signal terminal Data to the control electrode of the driving transistor DTFT. Here, the driving transistor DTFT may be turned on under control of the data signal. A voltage signal from the power signal terminal VDD is transmitted to the first electrode of the light-emitting unit through the driving transistor DTFT.

There is no pixel current passing through the switching transistor T1, and there is a pixel current passing through the driving transistor DTFT.

The size of the driving transistor DTFT is mainly related to mobility of the driving transistor DTFT and a magnitude of the pixel current flowing through the driving transistor DTFT. The larger the pixel current, the larger the size of the driving transistor DTFT, and the larger the size of the driving circuit.

In some examples, with continued reference to FIG. 1, the light-emitting device layer 2 is located on a side of the driving backplane 1.

The light-emitting device layer 2 includes a plurality of light-emitting units 21, a plurality of transparent electrodes 22 and a first bonding pattern 23.

The plurality of transparent electrodes 22 are located on surfaces of the plurality of light-emitting units 21 away from the driving backplane 1 and are electrically connected to the plurality of light-emitting units 21.

The term “transparent” means that light may pass through a transparent structure. For example, transmittance of the transparent structure in the embodiments of the present disclosure may reach 80% or above.

For example, the material of the plurality of transparent electrodes 22 includes at least one of indium tin oxide or indium zinc oxide.

The first bonding pattern 23 is located at least between the plurality of transparent electrodes 22. The first bonding pattern 23 is electrically connected to at least one transparent electrode 22.

The material used for the first bonding pattern 23 may be selected according to actual needs, and is not limited in the present disclosure.

For example, the first bonding pattern 23 may be formed using nickel (Ni) and tin (Sn), silver (Ag) and tin (Sn), gold (Au) and tin (Sn), a stack of gold (Au), or a eutectic alloy as the material.

It will be noted that the material of the transparent electrode is usually indium tin oxide or indium zinc oxide, and indium tin oxide or indium zinc oxide has a relatively large resistance.

The display substrate 100 provided by some embodiments of the present disclosure includes the driving backplane 1 and the light-emitting device layer 2. The light-emitting device layer 2 includes the plurality of light-emitting units 21, the plurality of transparent electrodes 22 and the first bonding pattern 23. The plurality of transparent electrodes 22 are located on the surfaces of the plurality of light-emitting units 21 away from the driving backplane 1. The first bonding pattern 23 is at least located between the plurality of transparent electrodes 22. The first bonding pattern 23 is electrically connected to at least one transparent electrode 22. In the present embodiments, the plurality of light-emitting units 21 are electrically connected by the connection between the first bonding pattern 23 and the plurality of transparent electrodes 22. Compared with that the plurality of light-emitting units 21 are electrically connected by a whole layer of transparent material in the related art, the resistance may be reduced, thereby achieving purpose of reducing the voltage drop, improving the luminous efficiency of the light-emitting units, reducing the power consumption, and improving the display properties of the display substrate.

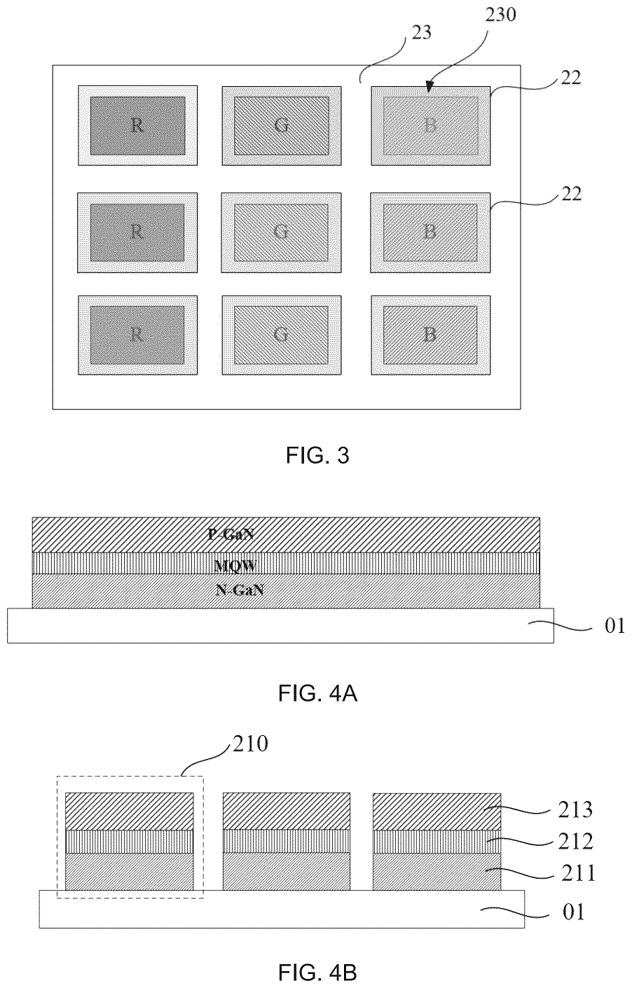

In some examples, referring to FIG. 3, the first bonding pattern 23 is further located around the plurality of transparent electrodes 22. In addition to being located between the plurality of transparent electrodes 22, the first bonding pattern 23 is also located around the plurality of transparent electrodes 22. Therefore, the plurality of transparent electrodes 22 are electrically connected. Moreover, on a basis of achieving a common cathode for the plurality of light-emitting units 21, compared with that the plurality of light-emitting units 21 are electrically connected by a whole layer of transparent material in the related art, the resistance may be reduced, thereby achieving purpose of reducing the voltage drop, improving the luminous efficiency of the light-emitting units, reducing the power consumption, and improving the display properties of the display substrate.

In some examples, with continued reference to FIG. 3, the first bonding pattern 23 includes a plurality of openings 230, at least one transparent electrode 22 is provided in an opening 230, and the transparent electrode(s) 22 located in the opening 230 are electrically connected to a wall of the opening 230. That is, the first bonding pattern 23 has openings 230 exposing the plurality of transparent electrodes 22, and transparent electrode(s) 22 located in an opening 230 are electrically connected to the wall of the opening 230, thereby realizing the common cathode for the plurality of light-emitting units 21.

In some embodiments, the first bonding pattern 23 includes a first pattern layer 231 and a second pattern layer 232 that are stacked, and the second pattern layer 232 is located on a side of the first pattern layer 231 away from the driving backplane 1.

In some examples, the material of the first pattern layer 231 includes a first metal material, and the material of the second pattern layer 232 includes a second metal material. A melting point of the first metal material is higher than a melting point of the second metal material.

For example, the first metal material is gold (Au), and the second metal material is indium (In). Alternatively, the first metal material is silver (Ag), and the second metal material is indium (In). Alternatively, the first metal material is plumbum (Pb), and the second metal material is indium (In). Alternatively, the first metal material is copper (Cu), and the second metal material is tin (Sn). Alternatively, the first metal material is gold (Au), and the second metal material is copper (Cu). The materials of the first metal material and the second metal material are not limited in the present disclosure.

In some examples, with continued reference to FIG. 3, a size of the second pattern layer 232 is larger than a size of the first pattern layer 231.

It will be noted that the description that “the size of the second pattern layer 232 is larger than the size of the first pattern layer 231” means that an area of an orthographic projection of the second pattern layer 232 on the driving backplane 1 is larger than an area of an orthographic projection of the first pattern layer 231 on the driving backplane 1.

In some embodiments, with continued reference to FIG. 1, the light-emitting unit 21 includes at least two stacked vertical light-emitting diodes 210, and a connection layer 220 located between two adjacent vertical light-emitting diodes 210.

In some examples, as shown in FIG. 1, the vertical light-emitting diode 210 includes an N-type semiconductor layer 211, a quantum well layer 212 and a P-type semiconductor layer 213.

In some examples, the N-type semiconductor layer 211 includes an N-type doped layer such as N—GaN, and the P-type semiconductor layer 213 includes a P-type doped layer such as P—GaN.

In some examples, in two adjacent stacked vertical light-emitting diodes 210, an N-type semiconductor layer of one vertical light-emitting diode 210 and a P-type semiconductor layer of the other vertical light-emitting diode are electrically connected by the connection layer 220.

It can be understood by those skilled in the art that a traditional GaN-based light-emitting diode (LED) upright structure makes an N-type electrode and a P-type electrode on the same side of a surface of a chip by dry etching. The current flows through a light-emitting area of the LED in a horizontal direction. Lateral injection of electrons from one electrode to another electrode leads to uneven distribution of current density along the way, which results in current crowding effect, uneven light emission, and uneven heat distribution, and easily causes rapid aging and failure of the device, thereby limiting a size of a single LED chip and the luminescence of the device.

Compared with the traditional GaN-based LED upright structure, in some embodiments of the present disclosure, two electrodes of the vertical light-emitting diode (LED) are placed on both sides of the LED films, and the current flows through the device perpendicularly to the surface of the films, so that an operating current density of a single chip may be significantly enhanced, which is conducive to expansion of the current, recombination of electrons and holes, and formation of a rather uniform light. In addition, the vertical light-emitting diode also has good heat dissipation, high luminous intensity, low power consumption, long life and other advantages.

In the present embodiments, the power consumption of the display substrate 100 may be reduced by using advantage of high luminous intensity of the vertical light-emitting diode 210, and a cross voltage of the light-emitting unit 21 may be enhanced by stacking at least two vertical light-emitting diodes 210, that is, connecting at least two vertical light-emitting diodes 210 in series, thereby further improving the luminous efficiency.

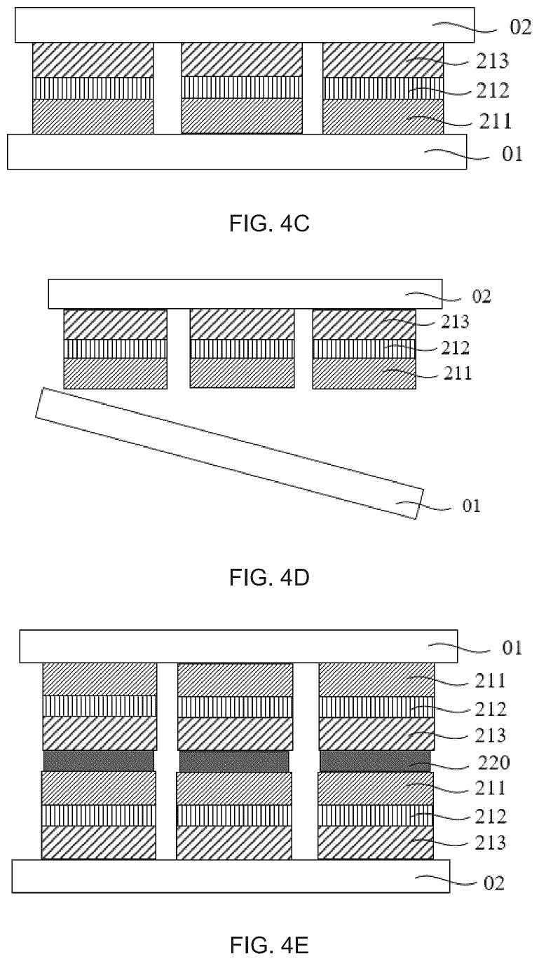

In some examples, referring to FIGS. 4A to 4E, FIGS. 4A to 4E are structural diagrams corresponding to all steps in a method for manufacturing stacked vertical light-emitting diodes.

The method for manufacturing the stacked vertical light-emitting diodes 210 includes following contents.

An N-type epitaxial layer, a quantum well epitaxial layer, and a P-type epitaxial layer are sequentially formed on a growth base 01 to obtain an epitaxial wafer structure, as shown in FIG. 4A.

The growth base 01 may be a silicon base, a sapphire base, or a silicon carbide base.

After the N-type epitaxial layer, the quantum well epitaxial layer, and the P-type epitaxial layer are formed, the N-type epitaxial layer, the quantum well epitaxial layer, and the P-type epitaxial layer are patterned to form a plurality of vertical light-emitting diodes, as shown in FIG. 4B. The vertical light-emitting diodes each include an N-type semiconductor layer 211, a quantum well layer 212 and a P-type semiconductor layer 213. The N-type semiconductor layer 211 is located in the N-type epitaxial layer, the quantum well layer 212 is located in the quantum well epitaxial layer, and the P-type semiconductor layer 213 is located in the P-type epitaxial layer.

The patterned epitaxial wafer structure is bonded to a surface of a supporting base 02, as shown in FIG. 4C.

The supporting base 02 may be a silicon base, a sapphire base, or a silicon carbide base, or may be a metal of copper (Cu), tungsten (W), molybdenum (Mo) or an alloy thereof.

The growth base 01 is removed, as shown in FIG. 4D.

A connection layer 220 is formed on a surface of the N-type semiconductor layer 211 of each of the vertical light-emitting diodes formed above away from the quantum well layers 212, and is bonded to another vertical light-emitting diode to form stacked vertical light-emitting diodes, as shown in FIG. 4E.

The another vertical light-emitting diode is formed on another growth base 01 and includes an N-type semiconductor layer 211, a quantum well layer 212 and a P-type semiconductor layer 213 that are provided away from the growth base 01 in sequence. Therefore, in the above steps, an N-type semiconductor layer of a vertical light-emitting diode and a P-type semiconductor layer of another vertical light-emitting diode may be electrically connected by the connection layer 220.

It will be noted that after the stacked vertical light-emitting diodes are formed, the growth base 01 or the supporting base 02 may be removed first; then the stacked vertical light-emitting diodes are bonded to the driving backplane; and then the supporting base 02 or the growth base 01 are removed. A plurality of light-emitting units 21 including at least two stacked vertical light-emitting diodes 210 are directly bonded to the driving backplane, compared with the related art in which single LED chips are bonded to the driving backplane one by one, so that the process may be simplified and the manufacturing cost may be saved.

In some embodiments, with continued reference to FIG. 1, the display substrate 100 further includes a reflective electrode layer 3. The reflective electrode layer 3 is located between the at least two stacked vertical light-emitting diodes 210 (i.e., the light-emitting unit 21) and the driving backplane 1.

The material used for the reflective electrode layer 3 may be selected according to actual needs, and is not limited in the present disclosure.

In some examples, the material of the reflective electrode layer 3 is aluminum (Al), titanium (Ti), nickel (Ni), or silver (Ag).

In some examples, the reflective electrode layer 3 has a Ni—Ag alternating stack structure.

It can be understood by those skilled in the art that the reflective electrode layer 3 may also be made of another metal with relatively high reflectivity.

In the present embodiments, the reflective electrode layer 3 is provided between the vertical light-emitting diode 210 and the driving backplane 1, so that light irradiated onto the reflective electrode layer 3 may exit after being reflected by the reflective electrode layer 3, thereby improving the light utilization rate.

In some embodiments, with continued reference to FIG. 1, the display substrate 100 further include an insulation structure 4 located between the plurality of light-emitting units 21 and between the first bonding pattern 23 and the driving backplane 1. The plurality of light-emitting units 21 are separated by the insulation structure 4 to prevent electrical crosstalk between the plurality of light-emitting units 21.

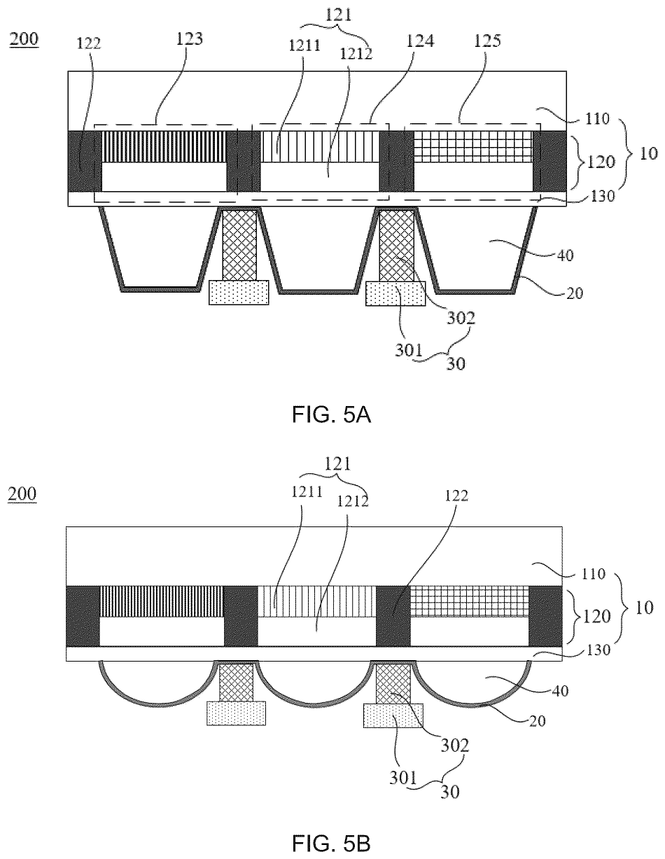

Some embodiments of the present disclosure provide an encapsulation substrate 200. As shown in FIGS. 5A and 5B, the encapsulation substrate 200 includes a substrate 10, an electrode connection layer 20 and a second bonding pattern 30. The electrode connection layer 20 is located on a side of the substrate 10.

For example, the electrode connection layer 20 has a transparent structure. For example, the material of the electrode connection layer 20 includes at least one of indium tin oxide or indium zinc oxide.

The second bonding pattern 30 is located on a side of the electrode connection layer 20 away from the substrate 10 and exposes at least part of the electrode connection layer 20.

The material used for the second bonding pattern 30 may be selected according to actual needs, and is not limited in the present disclosure.

For example, the second bonding pattern 30 may be formed using nickel (Ni) and tin (Sn), silver (Ag) and tin (Sn), gold (Au) and tin (Sn), a stack of gold (Au), or a eutectic alloy as the material.

In some embodiments, with continued reference to FIGS. 5A and 5B, the second bonding pattern 30 includes a third pattern layer 301 and a fourth pattern layer 302. The third pattern layer 301 is located on a side of the fourth pattern layer 302 away from the substrate 10.

In some examples, the material of the third pattern layer 301 includes a third metal material, and the material of the fourth pattern layer 302 includes a fourth metal material. A melting point of the fourth metal material is higher than a melting point of the third metal material.

For example, the fourth metal material is gold (Au), and the third metal material is indium (In). Alternatively, the fourth metal material is silver (Ag), and the third metal material is indium (In). Alternatively, the fourth metal material is plumbum (Pb), and the third metal material is indium (In). Alternatively, the fourth metal material is copper (Cu), and the third metal material is tin (Sn). Alternatively, the fourth metal material is gold (Au), and the third metal material is copper (Cu). The materials of the fourth metal material and the third metal material are not limited in the present disclosure.

In some examples, with continued reference to FIGS. 5A and 5B, a size of the third pattern layer 301 is larger than a size of the fourth pattern layer 302.

It will be noted that the description that “the size of the third pattern layer 301 is larger than the size of the fourth pattern layer 302” means that an area of an orthographic projection of the third pattern layer 301 on the driving backplane 1 is larger than an area of an orthographic projection of the fourth pattern layer 302 on the driving backplane 1.

In some embodiments, with continued reference to FIGS. 5A and 5B, the encapsulation substrate 200 further includes a plurality of lenses 40.

For example, the plurality of lenses 40 are located between the substrate 10 and the electrode connection layer 20, and the second bonding pattern 30 is at least located between the plurality of lenses 40.

The plurality of lenses 40 may be used to change the propagation direction of light incident on the encapsulation substrate 200.

In some examples, an orthographic projection of at least one lens 40 on the substrate 10 is in a shape of a circle, a square, or a rhombus. Of course, the orthographic projection of the at least one lens 40 on the substrate 10 may be in a shape of another irregular shape.

For example, as shown in FIG. 5B, at least one lens 40 is a convex lens. A surface of the lens 40 proximate to the substrate 10 is a plane, and a surface of the lens 40 away from the substrate 10 is a convex surface. As a result, the lens 40 has a function of converging light and may change the propagation direction of the light incident on the encapsulation substrate 200.

For example, as shown in FIG. 5A, at least one lens 40 has a trapezoidal structure.

In some embodiments, with continued reference to FIGS. 5A and 5B, the substrate 10 includes a base 110, a color filter layer 120 and an encapsulation layer 130.

The color filter layer 120 is located on a side of the base 110. The encapsulation layer 130 is located on a side of the color filter layer 120 away from the base 110. The encapsulation layer 130 is provided closer to the electrode connection layer 20 than the color filter layer 120.

In some examples, the encapsulation layer 130 is made of SiNx, SiOx, photoresist, or other organic materials.

In some examples, with continued reference to FIGS. 5A and 5B, the color filter layer 120 includes a plurality of color filter portions 121, and a light-shielding pattern 122 located between adjacent color filter portions 121.

In some examples, the plurality of color filter portions 121 include a red filter portion 123, a blue filter portion 124, and a green filter portion 125.

The red filter portion 123, the blue filter portion 124 and the green filter portion 125 are provided in different pixels. The light-shielding pattern 122 is provided between adjacent color filter portions 121 to separate the red filter portion 123, the blue filter portion 124 and the green filter portion 125, thereby avoiding color mixing of lights exiting from the red filter portion 123, the blue filter portion 123 and the green filter portion 125.

In some examples, the light-shielding pattern 122 is made of an inorganic material. In some other examples, the light-shielding pattern 122 is made of an organic material. In yet other examples, the light-shielding pattern 122 is made of a metal chromium or organic resin. The material of the light-shielding pattern 122 is not limited in the embodiments of the present disclosure.

In some examples, with continued reference to FIGS. 5A and 5B, an orthographic projection of the second bonding pattern 30 on the base 110 at least partially overlaps with an orthographic projection of the light-shielding pattern 122 on the base 110.

It will be noted that the description that “the orthographic projection of the second bonding pattern 30 on the base 110 at least partially overlaps with the orthographic projection of the light-shielding pattern 122 on the base 110” includes two cases that the orthographic projection of the second bonding pattern 30 on the base 110 partially overlaps with the orthographic projection of the light-shielding pattern 122 on the base 110, or the orthographic projection of the second bonding pattern 30 on the base 110 completely overlaps with the orthographic projection of the light-shielding pattern 122 on the base 110.

In some examples, with continued reference to FIGS. 5A and 5B, an orthographic projection of at least one lens 40 on the base 110 at least partially overlaps with an orthographic projection of the color filter portion 121 on the base 110. Therefore, the light incident on the color filter portion 121 may increase, thereby improving the light utilization rate.

In some embodiments, with continued reference to FIGS. 5A and 5B, the color filter portion 121 includes a color film layer 1211 and a quantum dot layer 1212 that are stacked.

The color film layer 1211 is provided closer to the base 110 than the quantum well layer 1212.

In some examples, the color film layer 1211 includes a color resist made of an organic photosensitive material, and the color resist may allow light within a specific wavelength range to pass through while block light within other wavelength ranges.

In some examples, the quantum dot layer 1212 includes quantum dots (QDs), and the quantum dots emit light under excitation of a light source, and light emitted by the quantum dot layer 1212 is white light.

In a case where light incident on the encapsulation substrate 200 is blue light, the quantum dot layer may include a red quantum dot material and a green quantum dot material. Then, under excitation of blue light, the red quantum dot material emits red light and the green quantum dot material emits green light. Thus, a mixed color light of red light, green light and blue light may be produced after passing through the quantum dot layer.

In the present embodiments, the color filter portion 121 includes the color film layer 1211 and the quantum dot layer 1212 that are stacked. The light incident on the color filter portion 121 excites the quantum dot layer 1212 to emit light. In a case of the same energy of the incident light, the brightness of the light exiting from the color filter portion 121 may be enhanced.

In a case where the color filter portion 121 includes the color film layer 1211 and the quantum dot layer 1212 that are stacked, the encapsulation layer 130 may play a role of encapsulating and protecting the quantum dot layer 1212, and may prevent the quantum dot layer 1212 from being in contact with external environment. Therefore, it may prevent moisture and oxygen in the external environment from affecting the luminescence performance of the quantum dots in the quantum dot layer 1212. The plurality of lenses 40 may change the propagation direction of the light incident on the encapsulation substrate 200, so that more light converges toward the color filter portion 121, and thus the light incident on the quantum dot layer 1212 may increase, thereby improving the excitation efficiency of the quantum dot material.

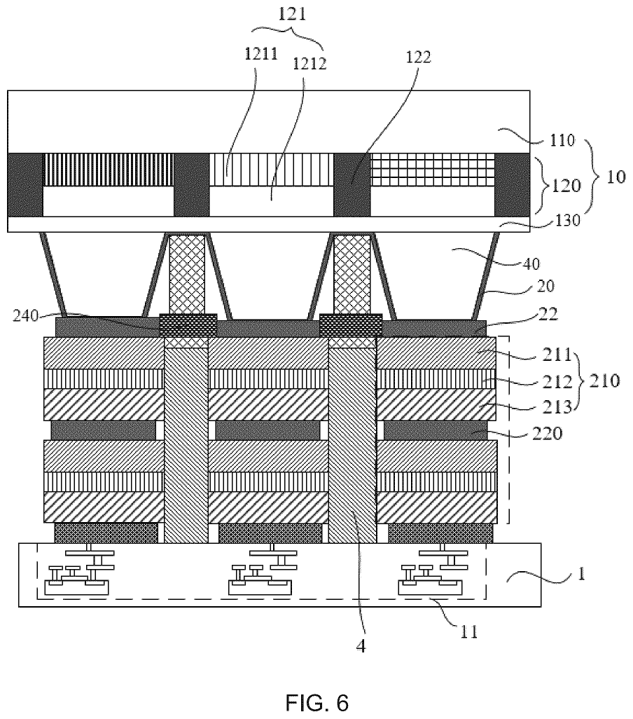

Some embodiments of the present disclosure provide a display apparatus 1000. As shown in FIG. 6, the display apparatus 1000 includes the above display substrate 100 and the above encapsulation substrate 200.

In some examples, the first bonding pattern 23 in the display substrate 100 is bonded to the second bonding pattern 30 in the encapsulation substrate 200, so that the plurality of transparent electrodes 22 in the display substrate 100 are in contact with the electrode connection layer 20 in the encapsulation substrate 200.

In a case where the first bonding pattern 23 includes the first pattern layer 231 and the second pattern layer 232 that are stacked, and the second bonding pattern 30 includes the third pattern layer 301 and the fourth pattern layer 302, the first metal material included in the first pattern layer 231 and the fourth metal material included in the fourth pattern layer 302 may be the same or different, and the second metal material included in the second pattern layer 232 and the third metal material included in the third pattern layer 301 may be the same or different, which are not limited in the embodiments of the present disclosure.

In some examples, the first metal material included in the first pattern layer 231 is the same as the fourth metal material included in the fourth pattern layer 302, and the second metal material included in the second pattern layer 232 is the same as the third metal material included in the third pattern layer 301. For example, the first metal material and the fourth metal material are gold (Au), and the second metal material and the third metal material are indium (In). Alternatively, the first metal material and the fourth metal material are silver (Ag), and the second metal material and the third metal material are indium (In). Alternatively, the first metal material and the fourth metal material are plumbum (Pb), and the second metal material and the third metal material are indium (In). Alternatively, the first metal material and the fourth metal material are copper (Cu), and the second metal material and the third metal material are tin (Sn). Alternatively, the first metal material and the fourth metal material are gold (Au), and the second metal material and the third metal material are copper (Cu).

The first bonding pattern 23 and the second bonding pattern 30 may be bonded by eutectic bonding or thermocompression bonding.

It can be understood by those skilled in the art that the eutectic bonding is a bonding process based on metal materials, in which a eutectic alloy serves as an intermediate metal layer by utilizing the property that a melting temperature of a certain eutectic alloy is lower than that of a single alloy component, and at a relatively low temperature, when two metals with similar lattices are heated above the eutectic temperature, atoms at the interface will diffuse into each other to form a eutectic alloy layer. The thermocompression bonding has no participation of liquid metal (i.e., solid-state diffusion occurs at the bonding interface), and is a metal bonding without intermediate products. In the thermocompression bonding, the diffusion rate of metal molecules on surfaces of two wafers is closely related to the metal type, temperature, pressure and surface roughness. Heating and applying pressure are both conducive to increase of the diffusion rate, and uniform pressure may improve bonding yield.

For example, with continued reference to FIG. 6, when the first bonding pattern 23 is bonded to the second bonding pattern 30, the second pattern layer 232 and the third pattern layer 301 diffuse into each other at a relatively low temperature to form a eutectic alloy layer 240, thereby realizing mechanical connection between the display substrate 100 and the encapsulation substrate 200. On this basis, the size of the second pattern layer 232 is larger than the size of the first pattern layer 231, and the size of the third pattern layer 301 is larger than the size of the fourth pattern layer 231. When the second pattern layer 232 and the third pattern layer 301 diffuse into each other to form the eutectic alloy layer 240, it may further ensure that the plurality of transparent electrodes 22 achieve rather good electrical connection by the eutectic alloy layer 240, thereby avoiding poor connection between the plurality of transparent electrodes 22.

In the present embodiments, when the first bonding pattern 23 and the second bonding pattern 30 are bonded to achieve mechanical connection between the display substrate 100 and the encapsulation substrate 200, the plurality of transparent electrodes 22 in the display substrate 100 are in contact with the electrode connection layer 20 in the encapsulation substrate 200.

In some examples, the display apparatus 1000 further includes a connection line and a cathode ring, and the electrode connection layer 20 is electrically connected to the cathode ring by the connection line, thereby introducing signals and power from the driving backplane.

In some examples, with continued reference to FIG. 6, orthographic projections of the plurality of light-emitting units 21 on the base 110 and orthographic projections of the plurality of color filter portions 121 on the base 110 at least partially overlap.

When the light emitted by the light-emitting unit 21 passes through the lens 40, the propagation direction of the light changes due to action of the lens 40, so that more light converges toward the color filter portion 121, and thus the light incident on the quantum dot layer 1212 may increase, thereby improving the excitation efficiency of the quantum dot material.

It can be understood that the display apparatus 1000 includes the above display substrate 100 and the above encapsulation substrate 200, and therefore has all the above beneficial effects, which are not repeated again here.

In some embodiments, the display apparatus 1000 may be any apparatus that displays images whether in motion (e.g., a video) or stationary (e.g., a still image), and regardless of text or image. More specifically, it is expected that the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display substrate, comprising: a driving backplane and a light-emitting device layer located on a side of the driving backplane, wherein
the light-emitting device layer includes:
a plurality of light-emitting units;
a plurality of transparent electrodes located on surfaces of the plurality of light-emitting units away from the driving backplane and electrically connected to the plurality of light-emitting units; and
a first bonding pattern located at least between the plurality of transparent electrodes;
the first bonding pattern being electrically connected to at least one transparent electrode.

2. The display substrate according to claim 1, wherein
the first bonding pattern is further located around the plurality of transparent electrodes.

3. The display substrate according to claim 2, wherein
the first bonding pattern has a plurality of openings, an opening is provided with at least one transparent electrode therein, and the at least one transparent electrode located in the opening is electrically connected to a wall of the opening.

4. The display substrate according to claim 1, wherein
the first bonding pattern includes a first pattern layer and a second pattern layer that are stacked, and the second pattern layer is located on a side of the first pattern layer away from the driving backplane.

5. The display substrate according to claim 4, wherein a material of the first pattern layer includes a first metal material, and a material of the second pattern layer includes a second metal material; and
a melting point of the first metal material is higher than a melting point of the second metal material.

6. The display substrate according to claim 4, wherein
a size of the second pattern layer is larger than a size of the first pattern layer.

7. The display substrate according to claim 1, wherein a light-emitting unit includes:
at least two stacked vertical light-emitting diodes; and
a connection layer located between two adjacent vertical light-emitting diodes in the at least two stacked vertical light-emitting diodes; wherein
the vertical light-emitting diodes each include an N-type semiconductor layer, a quantum well layer and a P-type semiconductor layer; and in the two adjacent stacked vertical light-emitting diodes, an N-type semiconductor layer of a vertical light-emitting diode and a P-type semiconductor layer of another vertical light-emitting diode are electrically connected by the connection layer.

8. The display substrate according to claim 7, further comprising:
a reflective electrode layer located between the at least two stacked vertical light-emitting diodes and the driving backplane.

9. The display substrate according to claim 7, further comprising:
an insulation structure located between the plurality of light-emitting units and between the first bonding pattern and the driving backplane.

10. An encapsulation substrate, including:
a substrate;
an electrode connection layer located on a side of the substrate; and
a second bonding pattern located on a side of the electrode connection layer away from the substrate and exposing at least part of the electrode connection layer.

11. The encapsulation substrate according to claim 10, wherein
the second bonding pattern includes a third pattern layer and a fourth pattern layer, and the third pattern layer is located on a side of the fourth pattern layer away from the substrate.

12. The encapsulation substrate according to claim 11, wherein
a material of the third pattern layer includes a third metal material, and a material of the fourth pattern layer includes a fourth metal material; and
a melting point of the fourth metal material is higher than a melting point of the third metal material.

13. The encapsulation substrate according to claim 11, wherein
a size of the third pattern layer is larger than a size of the fourth pattern layer.

14. The encapsulation substrate according to claim 10, further comprising:
a plurality of lenses located between the substrate and the electrode connection layer, wherein
the second bonding pattern is at least located between the plurality of lenses.

15. The encapsulation substrate according to claim 10, wherein the substrate includes:
a base;
a color filter layer located on a side of the base; and
an encapsulation layer located on a side of the color filter layer away from the base, wherein
the encapsulation layer is disposed closer to the electrode connection layer than the color filter layer.

16. The encapsulation substrate according to claim 15, wherein
the color filter layer includes a plurality of color filter portions and a light-shielding pattern located between adjacent color filter portions; and
an orthographic projection of the second bonding pattern on the base at least partially overlaps with an orthographic projection of the light-shielding pattern on the base.

17. The encapsulation substrate according to claim 16, wherein
a color filter portion includes a color film layer and a quantum dot layer that are stacked, wherein
the color film layer is disposed closer to the base than the quantum well layer.

18. A display apparatus, comprising:
the display substrate according to claim 1; and
an encapsulation substrate including:
a substrate;
an electrode connection layer located on a side of the substrate; and
a second bonding pattern located on a side of the electrode connection layer away from the substrate and exposing at least part of the electrode connection layer wherein
the first bonding pattern in the display substrate is bonded to the second bonding pattern in the encapsulation substrate, so that the plurality of transparent electrodes in the display substrate are in contact with the electrode connection layer in the encapsulation substrate.

19. The display apparatus according to claim 18, wherein
the second bonding pattern includes a third pattern layer and a fourth pattern layer, and the third pattern layer is located on a side of the fourth pattern layer away from the substrate.

20. The display apparatus according to claim 19, wherein
a material of the third pattern layer includes a third metal material, and a material of the fourth pattern layer includes a fourth metal material; and a melting point of the fourth metal material is higher than a melting point of the third metal material; and/or
a size of the third pattern layer is larger than a size of the fourth pattern layer.
